(19) United States
(12) Patent Application Publication
(10) Pub. No.: US 2012/0149177 A1
(43) Pub. Date: Jun. 14, 2012

(54) METHOD OF PRODUCING EPITAXIAL SILICON WAFER

(76) Inventors: Yuichi Nakayoshi, Tokyo (JP); Hironori Nishimura, Tokyo (JP)

(21) Appl. No.: 13/261,183

(22) PCT Filed: Aug. 6, 2010
(86) PCT No.: PCT/JP2010/063729

§ 371 Date: Feb. 17, 2012

(30) Foreign Application Priority Data
Aug. 19, 2009 (JP) 2009-190327

(51) Int. Cl. H01L 21/20

(52) U.S. Cl. 438/478; 257/E21.09

(57) ABSTRACT

An object of the invention is to provide an epitaxial silicon wafer in higher quality with good flatness and thickness uniformity. The object is achieved by a method characterized in that after an epitaxial film 20 is formed on a surface of a mirror polished silicon wafer 10, a grinding process, a polishing process, or a chemical etching process is performed only on the rear surface of the silicon wafer 10, and silicon precipitate 21 that adheres to an end portion of the rear surface of the silicon wafer 10 in the formation of the epitaxial film 20 is removed.

### TECHNICAL FIELD

The present invention relates to a method of producing an epitaxial silicon wafer, and in particular to a production method for obtaining a flat and high-quality epitaxial silicon wafer.

### RELATED ART

An epitaxial silicon wafer is a high-quality wafer formed by growing a single crystal silicon layer (epitaxial film) having a thickness of several micrometers on a silicon substrate mainly by vapor phase epitaxy. Epitaxial silicon wafers are advantageous in that wafers heavily doped with dopants such as boron (B) or phosphorus (P) can be produced in response to requests from device manufacturers or the like.

Further, high quality and flatness are required of epitaxial silicon wafers. For example, as disclosed in JP 04-122023 A (Patent Document 1), JP 08-17163 B (Patent Document 2), and JP 2006-190703 A (Patent Document 3), methods of producing an epitaxial silicon wafer are proposed in which a surface or both surfaces of the epitaxial silicon wafer after being provided with an epitaxial film are mirror polished. According to these methods, an epitaxial film surface is mirror polished, so that the flatness of the whole epitaxial silicon wafer can be controlled and an epitaxial silicon wafer having a certain level of flatness can be obtained.

### PRIOR ART DOCUMENTS

### Patent Documents

Patent Document 1: Japanese Patent Application Publication (JP-A) No. 04-122023

Patent Document 2: Japanese Examined Patent Application Publication (JP-B) No. 08-17163

Patent Document 3: Japanese Patent Application Publication (JP-A) No. 2006-190703

### DISCLOSURE OF THE INVENTION

### Problems to be Solved by the Invention

The inventions in the above three references are all effective in terms of obtaining epitaxial silicon wafers with good flatness. However, the inventions have a problem that when epitaxial film surfaces are mirror polished for planarization, defects (PIDs: polishing induced defects) or scratches and the like were found to be newly generated in the epitaxial film surfaces due to their high reactivity.

When epitaxial growth is performed, reactive gas used for forming an epitaxial film reaches the rear surface of the silicon substrate; accordingly, silicon precipitate adheres to an end portion of the rear surface of the silicon wafer. When the epitaxial film surface is mirror-polished with such silicon precipitate adhering to the end portion of the rear surface of the silicon wafer as described above, the flatness of the whole epitaxial wafer would be degraded, and device characteristics would be adversely affected.

An object of the invention is to provide a method of producing an epitaxial silicon wafer in higher quality with good flatness and thickness uniformity by performing a specified treatment only on the rear surface of a silicon wafer.

### Means for Solving the Problem

The present inventors have conducted many studies to solve the above problems to find the following facts. After forming an epitaxial film on a surface of a mirror polished silicon wafer, a grinding process, a polishing process, or a chemical etching process is performed only on the rear surface of the silicon wafer. Silicon precipitate that adheres to an end portion of the rear surface of the silicon wafer in the formation of the epitaxial film is removed, so that the generation of defects caused by the process performed on the epitaxial film can be prevented. Thus, a high-quality epitaxial film excellent in thickness uniformity can be obtained. In addition, since silicon precipitate on the end portion of the rear surface of the wafer can be selectively removed, high wafer flatness can also be realized.

In order to achieve the above object, the present invention primarily includes the following components.

(1) A method of producing an epitaxial silicon wafer, comprising the steps of: forming an epitaxial film on a surface of a mirror polished silicon wafer; then performing a grinding process, a polishing process, or a chemical etching process only on a rear surface of the silicon wafer; and removing silicon precipitate that adheres to an end portion of the rear surface of the silicon wafer in the formation of the epitaxial film.

(2) The method of producing an epitaxial silicon wafer according to (1) above, wherein a protective oxide film is formed on the surface of the epitaxial film for a pretreatment for removing the silicon precipitate.

(3) The method of producing an epitaxial silicon wafer according to (1) or (2) above, wherein the grinding process is a grinding process using fixed abrasive grains having a grain size of 1 μm or less.

(4) The method of producing an epitaxial silicon wafer according to (1) or (2) above, wherein the polishing process is minor polishing.

(5) The method of producing an epitaxial silicon wafer according to (1) or (2) above, wherein the chemical etching process is spin etching.

(6) The method of producing an epitaxial silicon wafer according to (2) above, wherein the protective oxide film has a thickness of 5 nm or more.

(7) The method of producing an epitaxial silicon wafer according to any one of (1) to (6) above, wherein the surface of the minor-polished silicon wafer has a GBIR (defined by SEMI standard) of 200 nm or less.

### Effect of the Invention

The present invention provides a method of producing an epitaxial silicon wafer in higher quality with good flatness and thickness uniformity.

### BRIEF DESCRIPTION OF THE DRAWINGS

FIGS. 1(a) to 1(c) show process steps for illustrating a method of producing an epitaxial silicon wafer according to the present invention.

FIGS. 2(a) to 2(e) show process steps for illustrating another embodiment of a method of producing an epitaxial silicon wafer according to the present invention.

FIGS. 3(a) to 3(c) show process steps for illustrating a conventional method of producing an epitaxial silicon wafer.

FIG. 4 is a cross-sectional view showing an example of a grinding apparatus used in the present invention.

FIG. 5 is a cross-sectional view showing an example of a polishing apparatus used in the present invention.

FIG. 6 is a cross-sectional view showing an example of an etching apparatus used in the present invention.

FIG. 7 is an observation showing defect distribution observed on a surface of each epitaxial silicon wafer manufactured in an example of the present invention and a comparative example.

FIG. 8 is a diagram showing a result of evaluating the flatness of each epitaxial silicon wafer manufactured in an example of the present invention and a comparative example.

### BEST MODE FOR CARRYING OUT THE INVENTION

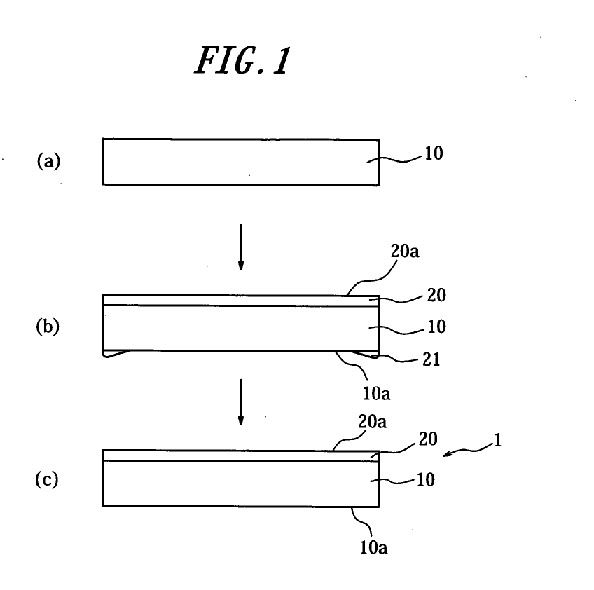

A method of producing an epitaxial silicon wafer according to the present invention will be described with reference to the drawings. A method of producing an epitaxial silicon wafer according to the present invention is a production method characterized in that, as shown in FIGS. 1(a) to 1(c), after an epitaxial film 20 is formed on a surface of a mirror-polished silicon wafer 10 (FIGS. 1(a) and (b)), a specified grinding, polishing, or chemical etching process is performed only on the rear surface of the silicon wafer, and silicon precipitate that adheres to an end portion of the rear surface of the silicon wafer in the formation of the epitaxial film is removed (FIG. 1(c)).

With the above method, a process for planarizing a surface 20a of the epitaxial film 20 is not added, so that defects (PIDs, scratches or the like) caused due to processing such as grinding, polishing, or the like can be prevented from generating. In addition, an epitaxial silicon wafer having an epitaxial film 20 excellent in thickness uniformity can be obtained. Further, silicon precipitate 21 on an end portion of a rear surface 10a of the wafer can be selectively removed; consequently, high flatness can also be realized.

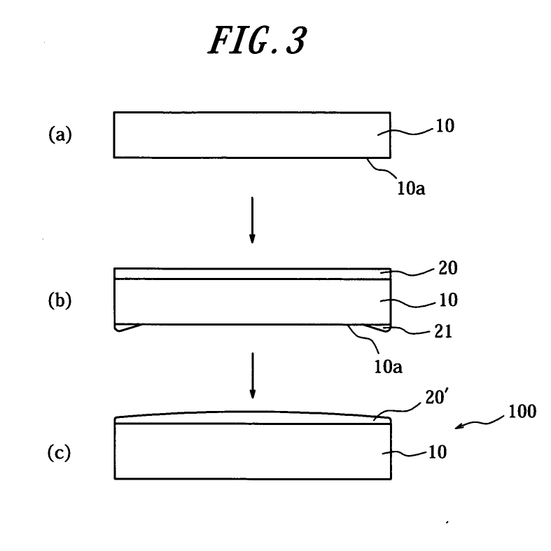

In contrast, in a conventional method of producing an epitaxial silicon wafer, the epitaxial film 20 is mirror-polished for the purpose of planarizing the epitaxial silicon wafer, defects (PIDs, scratches or the like) caused by processing cannot be prevented from generating on the epitaxial surface. Further, as shown in FIG. 3(c), when a surface of the epitaxial film 20 is mirror-polished with silicon precipitate 21 on an end portion of the rear surface 10a of the wafer, the thickness of the peripheral portion of the epitaxial film 20 would decrease (edge sagging), which results in the deterioration in the thickness evenness of the whole epitaxial silicon wafer.

Note that in a method of producing an epitaxial silicon wafer according to the present invention, in order to prevent defects from generating in the epitaxial film 20, the surface 20a of the epitaxial film 20 is not subjected to processing or etching on purpose.

Further, a surface of the mirror-polished silicon wafer 10 used in a production method of the present invention preferably has a GBIR (Global Back-side Ideal Range defined by SEMI standard) of 200 nm or less in terms of enabling the formation of the epitaxial film 20 on the surface with high accuracy. When the epitaxial film 20 is formed on a highly flat surface with a GBIR of 200 nm or less, the obtained epitaxial silicon wafer 1 can also be maintained to have high flatness.

Further, an epitaxial film formed on the silicon wafer 10 may be various epitaxial films depending on the use. The epitaxial film 20 can be formed on conditions in accordance with normal methods. For example, in a case of changing electric resistance, an epitaxial film 20 doped with antimony, arsenic, boron, or the like can be formed.

In a production method of the present invention, the rear surface 10a of the silicon wafer after epitaxial growth is preferably subjected to a grinding process. In particular, a grinding wheel (grinding plate) in which fixed abrasive grains having a grain size of 1 μm or less are embedded is more desirably used to grind the rear surface 10a of the silicon wafer. Thus, silicon precipitate 21 can be removed without fail, so that an epitaxial silicon wafer excellent in flatness, which has similar wafer surface quality to the case where mirror polishing is performed thereon. On the other hand, use of fixed abrasive grains having a size exceeding 1 μm would cause process damages such as flaws on the rear surface 10a of the silicon wafer 10.

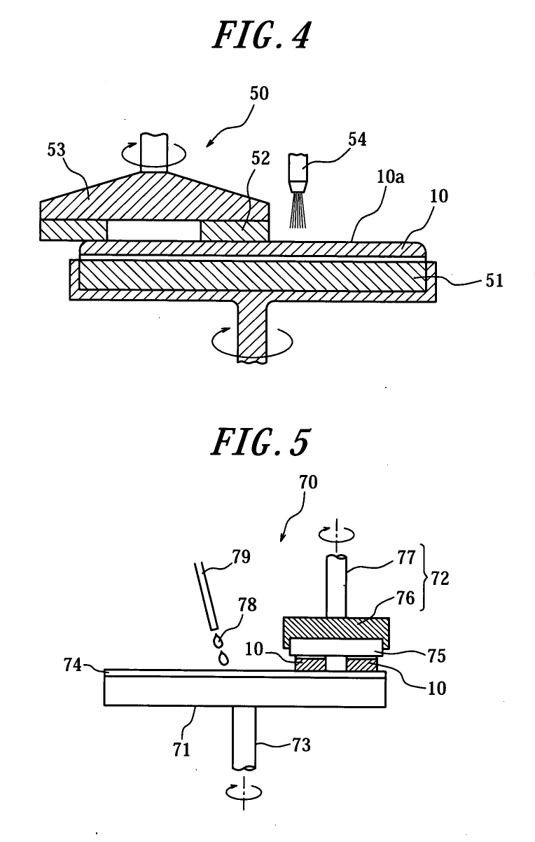

The grinding process is particularly performed using a grinding apparatus 50 shown in FIG. 4. As shown in FIG. 4, a revolving table 51, which is a process object holder on which an epitaxial silicon wafer 1 is to be placed, is provided around a vertical shaft to be rotatable with a drive mechanism (not shown). Further, a grind wheel 52 and a grind wheel support means 53 for supporting the grind wheel 52 are provided above the revolving table 51. This grind wheel support means 53 is provided such that the grind wheel 52 is rotatable around the vertical shaft using the drive mechanism (not shown). A feed water nozzle 54 for supplying grinding water to the rear surface 10a of the silicon wafer in grinding is also provided. After the epitaxial silicon wafer 1 is placed on the revolving table 51 such that the rear surface 10a to be ground is the upper surface, the grind wheel 52 in which fixed abrasive grains are embedded and the revolving table 51 are relatively rotated by the drive mechanism to perform grinding by pressing the grind wheel 52 to the end portion of the rear surface 10a of the silicon wafer. Further, as necessary, after the grinding process, the whole rear surface 10a of the silicon wafer may be subjected to polishing.

In a production method in accordance with the present invention, the rear surface 10a of the silicon wafer after epitaxial growth is preferably subjected to a polishing process, more preferably to mirror polishing. The mirror polishing is performed, so that the silicon precipitate 21 on the end portion of the rear surface can be positively removed without generating process damages or the like on the rear surface 10a of the silicon wafer.

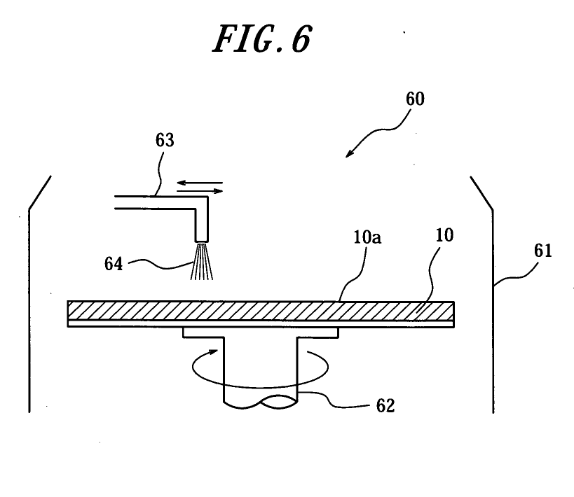

The polishing process is performed particularly using a polishing apparatus 70 shown in FIG. 5. This polishing apparatus 70 is a large circular disc, including a rotating surface plate 71 rotated by a shaft 73 connected to the center of the bottom surface of the apparatus and a wafer holder 72 composed of a pressure head 76 and a shaft 77 connected thereto for rotating the pressure head 76. A polishing cloth 74 is bonded to the upper surface of the rotating surface plate 71. A polishing plate 75 to which the silicon wafer 10 is fixed is attached to the lower surface of the pressure head 76. A supply tube 79 for supplying polishing fluid 78 is provided above the rotating surface plate 71. Then, the pressure head 76 to which the silicon wafer 10 is fixed is lowered to press the silicon wafer 10 with a predetermined pressure being applied thereto. While supplying the polishing fluid 78 from the supply tube 79 to the polishing cloth 74, the pressure head 76 and the rotating surface plate 71 are rotated in the same direction. Meanwhile, the rear surface 10a of the silicon wafer is pressed onto the polishing cloth 74 to allow polishing. Further, the polishing fluid 78 used may be whether one containing abrasive grains such as colloidal silica or one without abrasive grains.

Moreover, in a production method in accordance with the present invention, the given chemical etching process on the rear surface 10a of the silicon wafer after epitaxial growth is preferably single wafer processing spin etching. Using single wafer processing spin etching, the supply position for etchant supplied to the rear surface 10a of the silicon wafer, the number of rotations of the silicon wafer 10, and the like are controlled. Thus, the rear surface 10a of the wafer can be elaborated to a desired surface geometry, and besides, the silicon precipitate 21 only on the end portion of the rear surface can be removed.

Here, spin etching refers to a type of etching using a single wafer processing etching apparatus 60 as shown in FIG. 6. The silicon wafer 10 is horizontally set using a vacuum suction wafer chuck 62 placed inside a cup 61 such that the rear surface 10a of the silicon wafer is the upper surface. The silicon wafer 10 is spun by the wafer chuck 62. While an etchant supply nozzle 63 provided above the wafer 10 is horizontally transferred as shown by the arrow in FIG. 6, etchant 64 is supplied from the etchant supply nozzle 63 to the rear surface 10a of the rotating silicon wafer. Thus, the rear surface 10a of the wafer is etched to remove the silicon precipitate 21 on the end portion of the rear surface of the silicon wafer. Further, the etchant 64 is an aqueous solution containing hydrofluoric acid, nitric acid, and phosphoric acid (the mixing ratio of hydrofluoric acid, nitric acid, and phosphoric acid that are contained in the aqueous solution is defined as follows: hydrofluoric acid:nitric acid:phosphoric acid=0.5% to 40%:5% to 50:5% to 70% in mass fraction).

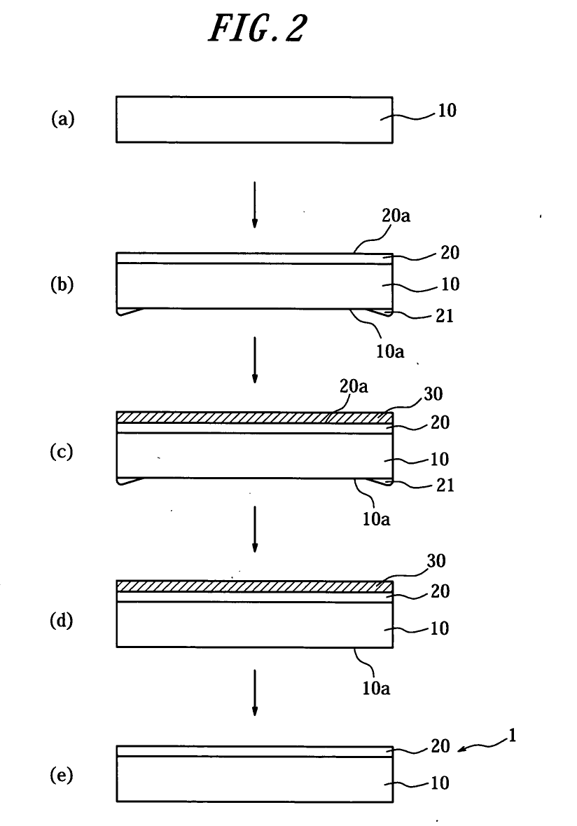

Further, as shown in FIGS. 2(a) to 2(c), for a pretreatment for removing the silicon precipitate 21 adhering to the rear surface 10a of the silicon wafer (FIG. 2(d)), a protective oxide film 30 is preferably formed on the surface 20a of the epitaxial film 20 (FIG. 2(c)). The protective oxide film 30 is provided, so that the rear surface 10a of the silicon wafer can be processed without a grinding apparatus, a polishing apparatus, and the like being directly in contact with the epitaxial film 20. When the protective oxide film 30 is not formed, a portion (for example, a wafer vacuum adsorption pad, or the like) of the apparatus contacts the surface 20a of the epitaxial film 20, which would cause generation of flaws or damages on a superficial portion of the epitaxial film 20.

The thickness of the protective oxide film 30 is preferably 5 nm or more. In a case where the thickness is less than 5 nm, the thickness is too small, which impairs the protective function. Accordingly, flaws or damages on the epitaxial film surface 20a would not be fully suppressed. On the other hand, when the thickness of the protective oxide film 30 exceeds 500 nm, more time is required for removing the protective oxide film 30 after removing the silicon precipitate 21 adhering to the end portion of the rear surface 10a of the wafer, and besides, warpage is caused in the wafer. Thus, the wafer flatness would be reduced.

Note that for a method for forming the protective oxide film 30, for example, silane gas and oxygen gas are introduced into an atmospheric pressure CVD apparatus to perform heat treatment at a temperature of about 400° C., so that the protective oxide film 30 having an intended thickness can be formed on the surface 20a of the epitaxial film 20.

For a method for removing the protective oxide film 30 formed on the epitaxial film 20, for example, etching using a HF aqueous solution may be employed. The process conditions such as the concentration of hydrofluoric acid and processing time may be determined as appropriate as long as the protective oxide film 30 can be entirely removed, unless undesired phenomenon such as redundant processing time or surface roughness is caused.

As for the grinding process and the polishing process, processing examples using a single side grinding apparatus and a single side polishing apparatus for processing only the rear surface 10a of the silicon wafer has been described. Alternatively, the protective oxide film 30 to be formed on the epitaxial film surface may be made thicker than the thickness of the silicon precipitate 21 adhering to the rear surface 10a of the silicon wafer, in which case a double side grinding apparatus or a double side polishing apparatus capable of processing front and rear surfaces can also be used.

Note that what has been described above is only to show exemplary embodiments of the present invention, and various modifications may be made within the scope of claims.

### EXAMPLE 1

For Example 1, as shown in FIGS. 1(a) to 1(c), after a 5 μm thick epitaxial film 20 was formed (FIG. 1(b)) on a surface of a mirror-polished silicon wafer 10 having a diameter of 300 mm, of which GBIR defined by SEMI standard was about 200 nm (FIG. 1(a)), mirror polishing was performed only on a rear surface 10a of the silicon wafer 10 to remove silicon precipitate 21 which adhered to an end portion of the rear surface 10a of the silicon wafer 10 (FIG. 1(c)) when an epitaxial film 20 was formed (FIG. 1(b)) (FIG. 1(c)), thus producing an epitaxial silicon wafer 1. Note that as shown in FIGS. 2(a) to 2(c), for a pretreatment for removing the silicon precipitate 21 which adhered to the rear surface 10a of the silicon wafer by single side polishing (FIG. 2(d)), silane gas and oxygen gas were introduced into a CVD apparatus to perform heat treatment at a temperature of about 400° C. Thus, a 5 nm thick protective oxide film 30 was formed on a surface 20a of the epitaxial film 20 (FIG. 2(c)). After that, a surface of the protective oxide film 30 formed on this epitaxial film 20 was retained using a vacuum adsorption pad, and mirror polishing was performed only on the rear surface 10a of the silicon wafer. Thus, the silicon precipitate 21 adhering to an end portion of the rear surface 10a was removed (FIG. 2(e)).

### EXAMPLE 2

In Example 2, as shown in FIG. 5, an epitaxial silicon wafer 1 was produced under conditions similar to Example 1 except for that silicon precipitate 21 adhering to an end portion of the rear surface 10a of a silicon wafer 10 was removed by a spin etching apparatus with the use of an aqueous solution containing hydrofluoric acid, nitric acid, and phosphoric acid as an etchant (FIG. 1(c)).

### COMPARATIVE EXAMPLE

For Comparable Example, as shown in FIGS. 3(a) to 3(c), an epitaxial silicon wafer 100 was produced under conditions similar to Example 1 except for that silicon precipitate 21 which adhered to an end portion of the rear surface 10a of a silicon wafer 10 was removed by simultaneously polishing the front surface of an epitaxial film 20 and the rear surface of the silicon wafer 10 by a double side polishing apparatus without forming a protective oxide film on the surface of the epitaxial film 20 (FIG. 3(c)).

### Evaluation of Quality of Epitaxial film

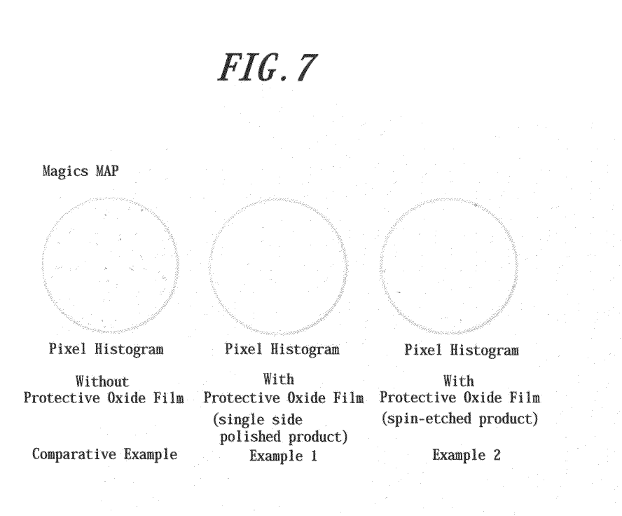

With respect to each of the epitaxial silicon wafers 1 and 100 produced in Example 1, Example 2, and Comparable Example, defect generation in the epitaxial film 20 was measured using a surface inspection system (Magics). The results are shown in FIG. 7. As shown by the results in FIG. 7, many defects were observed with respect to Comparable Example in which the surface of the epitaxial film 20 was polished, and 60 or more of the defects observed were PIDs, while only slight defects due to particles were observed and no PID was observed with respect to Examples 1 and 2.

### Evaluation of Flatness

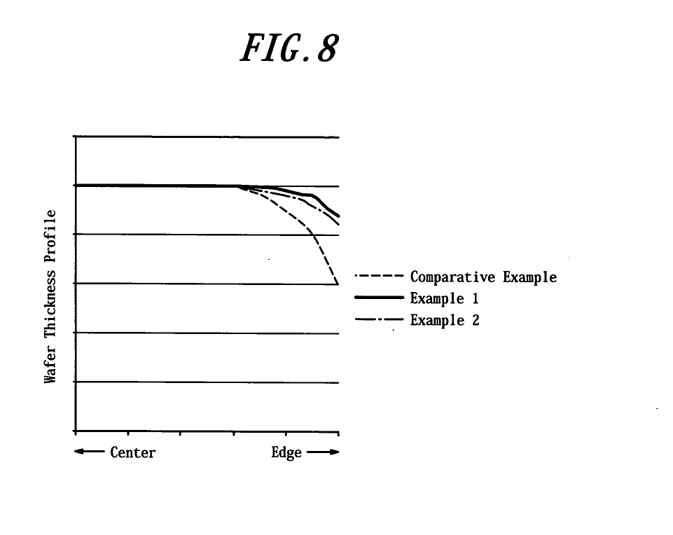

With respect to each of the epitaxial silicon wafers 1 and 100 produced in Example 1, Example 2, and Comparable Example, flatness (in partial sites) was measured using a flatness metrology system (WAFERSIGHT). The results (relative comparison) are shown in FIG. 8. As shown by FIG. 8, with respect to Comparable Example in which the surface of the epitaxial film 20 was polished, the thickness of the epitaxial film at the peripheral portion was observed to have decreased significantly (edge sagging), while uniform film thickness distribution was obtained across almost the entire surface of the wafers of Examples 1 and 2.

### INDUSTRIAL APPLICABILITY

According to the present invention, an epitaxial silicon wafer in higher quality with good flatness and thickness uniformity can be provided.

### EXPLANATION OF REFERENCE

1, 100: epitaxial silicon wafer;

10: silicon wafer;

20: epitaxial film;

21: silicon precipitate;

30: protective oxide film;

50: grinding apparatus;

51: revolving table;

52: grind wheel;

53: grind wheel support means;

54: feed water nozzle;

60: single wafer processing etching apparatus;

61: cup;

62: wafer chuck;

63: etchant supply nozzle;

64: etchant;

70: polishing apparatus;

71: rotating surface plate;

72: wafer holder,

73: shaft;

74: polishing cloth;

75: polishing plate;

76: pressure head;

77: shaft;

78: polishing fluid;

79: supply tube.

1. A method of producing an epitaxial silicon wafer, comprising the steps of:
forming an epitaxial film on a surface of a mirror polished silicon wafer;
then performing a grinding process, a polishing process, or a chemical etching process only on a rear surface of the silicon wafer; and
removing silicon precipitate that adheres to an end portion of the rear surface of the silicon wafer in the formation of the epitaxial film.

2. The method of producing an epitaxial silicon wafer according to claim 1, wherein a protective oxide film is formed on the surface of the epitaxial film for a pretreatment for removing the silicon precipitate.

3. The method of producing an epitaxial silicon wafer according to claim 1 or claim 2, wherein the grinding process is a grinding process using fixed abrasive grains having a grain size of 1 μm or less.

4. The method of producing an epitaxial silicon wafer according to claim 1 or claim 2, wherein the polishing process is mirror polishing.

5. The method of producing an epitaxial silicon wafer according to claim 1 or claim 2, wherein the chemical etching process is spin etching.

6. The method of producing an epitaxial silicon wafer according to claim 2, wherein the protective oxide film has a thickness of 5 nm or more.

7. The method of producing an epitaxial silicon wafer according to any one of claims 1 to 6, wherein the surface of the mirror-polished silicon wafer has a GBIR (defined by SEMI standard) of 200 nm or less.
